(19) United States
(12) Patent Application Publication
(10) Pub. No.: US 2026/0344046 A1
(43) Pub. Date: Oct. 29, 2026

(54) DISPLAY PANEL AND DISPLAY APPARATUS

(71) Applicants: Chengdu BOE Optoelectronics Technology Co., Ltd., Sichuan Province (CN); BOE Technology Group Co., Ltd., Beijing (CN)

(72) Inventors: Ting LI, Beijing (CN); Yadong ZHANG, Beijing (CN); Yuanming FENG, Beijing (CN); Pengcheng ZANG, Beijing (CN); Changyi WANG, Beijing (CN)

(21) Appl. No.: 18/995,321

(22) PCT Filed: Oct. 8, 2023
(86) PCT No.: PCT/CN2023/123434

§ 371 Date: Jan. 16, 2025

(51) Int. Cl. H10D 86/40; H10D 86/60

(52) U.S. Cl. CPC H10D 86/421; H10D 86/441; H10D 86/60

(57) ABSTRACT

A display panel and a display apparatus. The display panel includes: a base substrate, a gate conductive layer on the base substrate, a gate insulating layer on a side of the gate conductive layer facing away from the base substrate, a semiconductor layer on a side of the gate insulating layer facing away from the base substrate, an etch barrier layer on a side of the semiconductor layer facing away from the base substrate, and a source-drain layer on a side of the etch barrier layer facing away from the base substrate. The etch barrier layer includes a first contact hole. The source-drain layer is connected with the semiconductor layer through the first contact hole.

### CROSS REFERENCE TO RELATED APPLICATIONS

This application is a national phase entry under 35 U.S.C. § 371 of International Application No. PCT/CN2023/123434, filed on Oct. 8, 2023, the entire content of which is incorporated herein by reference.

### TECHNICAL FIELD

The disclosure relates to the field of display technology, in particular to a display panel and a display apparatus.

### BACKGROUND

Thin Film Transistors (TFTs) are currently the main driving components in Liquid Crystal Displays (LCDs) and Active Matrix Organic Light-Emitting Diode (AMOLED) displays, directly affecting the display performance of these devices. Most of the liquid crystal displays on the market are backlit LCDs, which include a liquid crystal display panel and a backlight module. Oxide semiconductor materials such as Indium Gallium Zinc Oxide (IGZO), which have high mobility and on-state current, are widely used in display apparatuses. However, current technologies may cause oxide products to become conductors, resulting in damage and thus affecting performance.

Taking LCDs and AMOLEDs as examples, both include array substrates, with a large number of data lines and gate lines on these substrates. However, at the overlapping portions of the gate lines and data lines, electrostatic breakdown (Electro-Static Discharge, ESD) frequently occurs due to the release of charges on the data and gate lines, causing short circuits between them and leading to display defects.

### SUMMARY

A display panel according to embodiments of the disclosure, includes: a base substrate, a gate conductive layer on the base substrate, a gate insulating layer on a side of the gate conductive layer facing away from the base substrate, a semiconductor layer on a side of the gate insulating layer facing away from the base substrate, an etch barrier layer on a side of the semiconductor layer facing away from the base substrate, and a source-drain layer on a side of the etch barrier layer facing away from the base substrate. The etch barrier layer includes a first contact hole. The source-drain layer is connected with the semiconductor layer through the first contact hole.

In some possible implementations, the display panel includes a shift register, and the shift register includes an output transistor. The semiconductor layer includes an active layer of the output transistor, and the source-drain layer includes a first electrode and a second electrode of the output transistor. The first contact hole includes a first sub-contact hole and a second sub-contact hole. The first electrode is connected with the active layer through the first sub-contact hole, and the second electrode is connected with the active layer through the second sub-contact hole. The etch barrier layer further includes a second contact hole. An orthographic projection of the second contact hole on the base substrate is located between orthographic projections of the first electrode and second electrode on the base substrate. The orthographic projection of the second contact hole on the base substrate and an orthographic projection of the active layer on the base substrate have an overlapping region. The source-drain layer further includes a first dummy electrode. An orthographic projection of the first dummy electrode on the base substrate is located between the orthographic projections of the first electrode and second electrode on the base substrate, and covers the orthographic projection of the second contact hole on the base substrate.

In some possible implementations, the active layer includes multiple sub-active layers arranged at intervals along a first direction. The first electrode, the first dummy electrode, and the second electrode are arranged at intervals along a second direction. Each sub-active layer of the multiple sub-active layers corresponds to the first sub-contact hole, the second sub-contact hole, and the second contact hole.

In some possible implementations, the first sub-contact hole, the second contact hole, and the second sub-contact hole are arranged at intervals along the second direction. An edge of the first sub-contact hole and an edge of the second contact hole are separated by a first length along the second direction. An edge of the second sub-contact hole and an edge of the second contact hole are separated by a second length along the second direction. The ratio between the first length and the second length ranges from 0.8 to 1.

In some possible implementations, a width of the active layer in the first direction is indicated as a first width, a width of the first sub-contact hole in the first direction is indicated as a second width, a width of the second sub-contact hole in the first direction is indicated as a third width, and a width of the second contact hole in the first direction is indicated as a fourth width. At least one of the second width, third width, or fourth width is greater than the first width.

In some possible implementations, two or more of the second width, third width, and fourth width are equal.

In some possible implementations, the base substrate includes a display region and a non-display region. The display region is provided with an array of sub-pixels, and the non-display region includes a first region. The first region is provided with multiple cascaded shift registers, multiple transfer holes, and multiple common voltage signal lines, and includes a first dummy fill region, and a second dummy fill region. An orthographic projection of the shift registers and an orthographic projection of the sub-pixels on the base substrate are at different sides of the orthographic projection of the common voltage signal lines on the base substrate. An orthographic projection of the transfer holes on the base substrate is located between the orthographic projection of the shift registers and the orthographic projection of the common voltage signal lines on the base substrate. An orthographic projection of the first dummy fill region on the base substrate is located between the orthographic projection of the sub-pixels and the orthographic projection of the common voltage signal lines on the base substrate. The first dummy fill region is provided with multiple second dummy electrodes arranged at intervals. An orthographic projection of the second dummy fill region on the base substrate is located between the orthographic projection of the transfer holes and the orthographic projection of the common voltage signal lines on the base substrate. The second dummy fill region is provided with multiple second dummy electrodes arranged at intervals. The first region is located at the corner of the base substrate.

In some possible implementations, the non-display region further includes a second region. The second region includes multiple cascaded shift registers, multiple transfer electrodes, multiple common voltage signal lines, multiple data fan-out lines, a third dummy fill region, a fourth dummy fill region, and a fifth dummy fill region. An orthographic projection of the shift registers and an orthographic projection of the sub-pixels on the base substrate are at different sides of an orthographic projection of the common voltage signal lines on the base substrate. An orthographic projection of the transfer electrodes on the base substrate is located between the orthographic projection of the shift registers and the orthographic projection of the common voltage signal lines on the base substrate. An orthographic projection of the data fan-out lines on the base substrate is located between the orthographic projection of the common voltage signal lines and the orthographic projection of the sub-pixels on the base substrate. An orthographic projection of the third dummy fill region on the base substrate is located between the orthographic projection of the sub-pixels and the orthographic projection of the data fan-out lines on the base substrate. The third dummy fill region is provided with multiple second dummy electrodes arranged at intervals. An orthographic projection of the fourth dummy fill region on the base substrate is located between the orthographic projection of the common voltage signal lines and the orthographic projection of the data fan-out lines on the base substrate. The fourth dummy fill region is provided with multiple second dummy electrodes arranged at intervals. An orthographic projection of the fifth dummy fill region on the base substrate is located between the orthographic projection of the common voltage signal lines and the orthographic projection of the transfer electrodes on the base substrate. The fifth dummy fill region is provided with multiple second dummy electrodes arranged at intervals. The second region is located at the corner of the base substrate.

In some possible implementations, the non-display region further includes a third region. The third region includes a grid-shaped hollow region formed by multiple intersecting common signal lines, a transfer region, a dummy transistor region, a sixth dummy fill region, and a seventh dummy fill region. An orthographic projection of the transfer region on the base substrate overlaps with an orthographic projection of part of the common signal lines on the base substrate. An orthographic projection of the dummy transistor region on the base substrate is located between the orthographic projection of the transfer region and the orthographic projection of the sub-pixels on the base substrate. An orthographic projection of the sixth dummy fill region on the base substrate overlaps with an orthographic projection of the grid-shaped hollow region on the base substrate. The sixth dummy fill region is provided with multiple second dummy electrodes arranged at intervals. An orthographic projection of the seventh dummy fill region on the base substrate is located between the orthographic projection of the dummy transistor region and the orthographic projection of the transfer region on the base substrate. The seventh dummy fill region is provided with multiple second dummy electrodes arranged at intervals.

In some possible implementations, the non-display region further includes a fourth region. The fourth region is provided with multiple input terminals, multiple first conductive signal lines, multiple second conductive signal lines, multiple test signal lines, and multiple second dummy electrodes, where the multiple second dummy electrodes are arranged at intervals. The multiple test signal lines correspond one-to-one with the multiple input terminals. The first conductive signal lines are located at two sides of the input terminals, while the second conductive signal lines are located at one side of the input terminals. The orthographic projection of the second dummy electrodes on the base substrate does not overlap with the orthographic projections of the first conductive signal lines, the input terminals, and the second conductive signal lines on the base substrate. The orthographic projection of the second dummy electrodes on the base substrate overlap with or does not overlap with the orthographic projections of the multiple test signal lines on the base substrate.

In some possible implementations, a spacing between adjacent second dummy electrodes along a first direction is indicated as a first spacing, and a spacing between adjacent second dummy electrodes along a second direction is indicated as a second spacing. A length of the second dummy electrode, a width of the second dummy electrode, the first spacing and the second spacing are kept between 2 micrometers and 10 micrometers.

In some possible implementations, the etch barrier layer has multiple first through holes, and at least one second dummy electrode corresponds to at least one first through hole. The orthographic projection of the second dummy electrode on the base substrate covers the orthographic projection of the corresponding first through hole on the base substrate.

In some possible implementations, the etch barrier layer further has at least one transfer dummy hole. An orthographic projection of the transfer dummy hole on the base substrate does not overlap with the orthographic projection of the shift register on the base substrate. The shift register is located in a first shift register region, and the transfer dummy hole is located in the first shift register region. The first shift register region is located at a corner of the base substrate.

In some possible implementations, the transfer dummy hole passes through the gate insulating layer. The first insulating layer is disposed on a side of the source and drain electrodes facing away from the base substrate, and the transfer dummy hole passes through the first insulating layer. The second insulating layer is disposed on the side of the first insulating layer facing away from the base substrate, and the transfer dummy hole further passes through the second insulating layer.

In some possible implementations, the gate conductive layer includes multiple gate lines, and the display panel further includes at least one dummy transistor. One end of at least one gate line among the multiple gate lines is connected with at least one dummy transistor.

In some possible implementations, a same end of each gate line among the multiple gate lines is connected with at least one dummy transistor.

In some possible implementations, the display panel includes a display region and a non-display region. The display region is provided with an array of sub-pixels. The non-display region is provided with multiple shift registers, and the display region is provided with multiple gate lines. The multiple shift registers and multiple gate lines are correspondingly connected. An orthographic projection of at least one dummy transistor on the base substrate is located between the orthographic projection of the shift register on the base substrate and the orthographic projection of the correspondingly connected gate line on the base substrate.

In some possible implementations, the multiple shift registers are located in a second shift register region. The shift registers in the second shift register region are arranged sequentially along the second direction. The orthographic projection of the dummy transistors on the base substrate is located between the orthographic projection of the sub-pixels and an orthographic projection of the second shift register region on the base substrate. The dummy transistor is located at a side away from the sub-pixels along the first direction. Orthographic projections of adjacent dummy transistors on the base substrate are opposite each other along the second direction.

In some possible implementations, the multiple shift registers are located in a third shift register region, and multiple data fan-out lines are provided between the third shift register region and the sub-pixels. An orthographic projection of a dummy transistor connected with an end of the gate line near the shift registers is located between the orthographic projection of the data fan-out lines and the orthographic projection of the sub-pixels on the base substrate. The dummy transistor is located at a side away from the sub-pixels along the first direction. Orthographic projections of adjacent dummy transistors on the base substrate are opposite each other along the second direction.

In some possible implementations, the semiconductor layer further includes a first active layer and a second active layer of the dummy transistor. The source-drain layer further includes a first electrode and a second electrode of the dummy transistor. The etch barrier layer further includes a third contact hole and a fourth contact hole. The first electrode of the dummy transistor is connected with the first active layer through the third contact hole, and the second electrode of the dummy transistor is connected with the second active layer through the fourth contact hole.

In some possible implementations, the first active layer and the second active layer are arranged at intervals along the second direction, and the first electrode and the second electrode of the dummy transistor are arranged at intervals along the second direction.

A display apparatus according to embodiments of the disclosure includes the above display panel.

### BRIEF DESCRIPTION OF FIGURES

FIG. 1 illustrates a sectional view along line CC′ of some structures of a display panel according to embodiments of the disclosure.

FIG. 2 is a schematic diagram of some of equivalent circuit of a shift register according to embodiments of the disclosure.

FIG. 3 is a schematic diagram of some structures of a shift register according to embodiments of the disclosure.

FIG. 4 is a schematic diagram of some structures of a display panel according to embodiments of the disclosure.

FIG. 5 is another schematic diagram of some structures of a display panel according to embodiments of the disclosure.

FIG. 6 is another schematic diagram of some structures of a display panel according to embodiments of the disclosure.

FIG. 7 is another schematic diagram of some structures of a display panel according to embodiments of the disclosure.

FIG. 8 is another schematic diagram of some structures of a display panel according to embodiments of the disclosure.

FIG. 9 is another schematic diagram of some structures of a display panel according to embodiments of the disclosure.

FIG. 10 is another schematic diagram of some structures of a display panel according to embodiments of the disclosure.

FIG. 11 is another schematic diagram of some structures of a display panel according to embodiments of the disclosure.

FIG. 12 is another schematic diagram of some structures of a display panel according to embodiments of the disclosure.

FIG. 13 is another schematic diagram of some structures of a display panel according to embodiments of the disclosure.

FIG. 14 is another schematic diagram of some structures of a display panel according to embodiments of the disclosure.

FIG. 15 is another schematic diagram of some structures of a display panel according to embodiments of the disclosure.

FIG. 16 is another schematic diagram of some structures of a display panel according to embodiments of the disclosure.

FIG. 17 is another schematic diagram of some structures of a display panel according to embodiments of the disclosure.

FIG. 18 is another schematic diagram of some structures of a display panel according to embodiments of the disclosure.

FIG. 19 is another schematic diagram of some structures of a display panel according to embodiments of the disclosure.

FIG. 20 is another schematic diagram of some structures of a display panel according to embodiments of the disclosure.

FIG. 21 is another schematic diagram of some structures of a display panel according to embodiments of the disclosure.

FIG. 22 is another schematic diagram of some structures of a display panel according to embodiments of the disclosure.

FIG. 23 is another schematic diagram of some structures of a display panel according to embodiments of the disclosure.

FIG. 24 is another schematic diagram of some structures of a display panel according to embodiments of the disclosure.

FIG. 25 is another schematic diagram of some structures of a display panel according to embodiments of the disclosure.

FIG. 26 is another schematic diagram of some structures of a display panel according to embodiments of the disclosure.

FIG. 27 is another schematic diagram of some structures of a display panel according to embodiments of the disclosure.

### DETAILED DESCRIPTION

To make the objectives, technical solutions, and advantages of embodiments of the disclosure clearer, the technical solutions of the embodiments of the disclosure will be clearly and completely described below in conjunction with the accompanying drawings. Apparently, the described embodiments are some, not all, of the embodiments of the disclosure. The embodiments in the disclosure and the features in the embodiments may be combined with each other without conflict. Based on the described embodiments of the disclosure, all other embodiments obtained by those of ordinary skill in the art without inventive efforts fall within the protection scope of the disclosure.

Unless otherwise indicated, technical terms or scientific terms used herein should have the usual meaning understood by those skilled in the art to which the disclosure belongs. The terms “first,” “second,” and similar words used in the description and claims of the disclosure do not indicate any sequence, quantity, or importance, but are merely used to distinguish different components. Words such as “comprise” or “include” indicate that the elements or objects appearing before the word cover the elements or objects listed after the word and their equivalents, without excluding other elements or objects. Words such as “connected” or “coupled” are not limited to physical or mechanical connections but may include electrical connections, whether direct or indirect.

It should be noted that sizes and shapes of all figures in the drawings do not reflect a true scale and are only intended to illustrate the contents of the disclosure. Same or similar reference signs indicate same or similar elements or elements with the same or similar function throughout the disclosure.

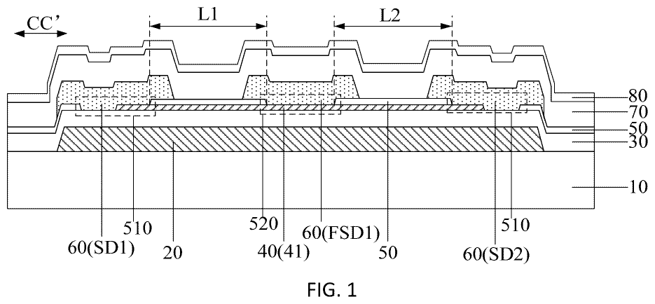

As shown in FIG. 1, a display panel according to embodiments of the disclosure includes: a base substrate 10, a gate conductive layer 20 on the base substrate 10, a gate insulating layer 30 on a side of the gate conductive layer 20 facing away from the base substrate 10, a semiconductor layer 40 on a side of the gate insulating layer 30 facing away from the base substrate 10, an etch barrier layer 50 on a side of the semiconductor layer 40 facing away from the base substrate 10, and a source-drain layer 60 on a side of the etch barrier layer 50 facing away from the base substrate 10.

The etch barrier layer 50 includes the first contact hole 510, and the source-drain layer 60 is connected with the semiconductor layer 40 through the first contact hole 510.

In disclosure, by arranging the base substrate, gate conductive layer, semiconductor layer, etch barrier layer, and source-drain layer, and allowing the source-drain layer to connect with the semiconductor layer through the first contact hole in the etch barrier layer, it can be ensured that the etching and other processes on the source-drain layer and etch barrier layer will not adversely affect the characteristics of oxide products in the display panel, thereby solving the problem of the oxide product becoming a conductor, which reduces the damage and improves the performance.

It should be noted that the etch barrier layer can serve as a protection layer during the etching process on the source-drain layer to prevent damage to the semiconductor layer, thereby avoiding adverse effects on the product.

Exemplarily, as shown in FIG. 1, the display panel further includes: a first insulating layer 70 on a side of the source-drain layer 60 facing away from the base substrate, and a second insulating layer 80 on a side of the first insulating layer 70 facing away from the base substrate.

Exemplarily, the gate conductive layer and source-drain layer can be made of conductive materials, such as metals like Titanium (Ti), Gold (Au), Silver (Ag), Molybdenum (Mo), Copper (Cu), Aluminum (Al), etc., which is not limited here.

Exemplarily, the material of the semiconductor layer can include oxide, amorphous silicon, or low-temperature polycrystalline silicon, which is not limited here.

Exemplarily, the gate insulating layer, etch barrier layer, first insulating layer, and second insulating layer can all be made of insulating materials. Depending on the need, organic insulating materials like polyimide or resin can be used, or inorganic insulating materials like silicon oxide, silicon nitride, or silicon oxynitride can be used. In the embodiments of the disclosure, the materials of each functional layer are not specifically limited.

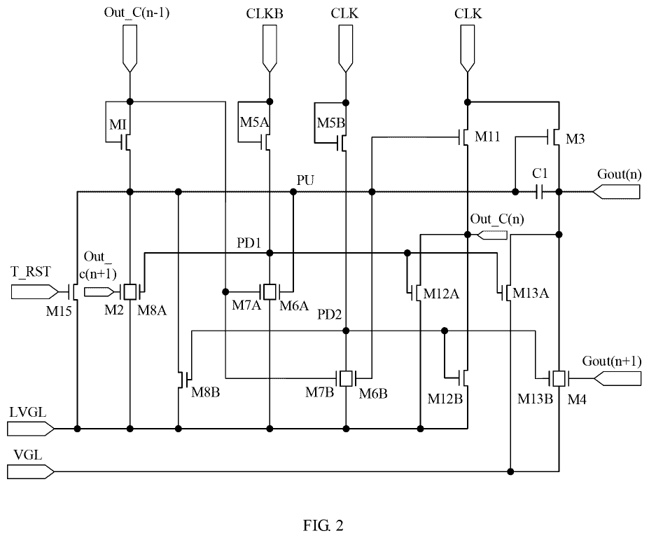

Exemplarily, as shown in FIG. 2, an equivalent circuit diagram of a shift register includes: a first transistor M1, a second transistor M2, a third transistor M3, an output transistor M4, a fifth transistor M5A, a fifth control transistor M5B, a sixth transistor M6A, a sixth control transistor M6B, a seventh transistor M7A, a seventh control transistor M7B, an eighth transistor M8A, an eighth control transistor M8B, an eleventh transistor M11, a twelfth transistor M12A, a twelfth control transistor M12B, a thirteenth transistor M13A, a thirteenth control transistor M13B, a fifteenth transistor M15, and a first capacitor C1. A gate electrode of the first transistor M1 is coupled to a first electrode of the first transistor M1, the first electrode of the first transistor M1 is coupled to a first output control signal terminal Out_C(n−1), and a second electrode of the first transistor M1 is coupled to a first electrode of the second transistor M2. A gate electrode of the second transistor M2 is coupled to a third output control signal terminal Out_C(n+1), and a second electrode of the second transistor M2 is coupled to a first level signal terminal LVGL. A gate electrode of the third transistor M3 is coupled to a first electrode of the first capacitor C1, a first electrode of the third transistor M3 is coupled to a first clock signal terminal CLK, and a second electrode of the third transistor M3 is coupled to a first cascade output terminal Gout(n). A second electrode of the first capacitor C1 is coupled to the first cascade output terminal Gout(n). A gate electrode of the output transistor M4 is coupled to a second cascade output terminal Gout(n+1), a first electrode of the output transistor M4 is coupled to the second electrode of the third transistor M3, and a second electrode of the output transistor M4 is coupled to a second level signal terminal VGL. A gate electrode of the fifth transistor M5A is coupled to a first electrode of the fifth transistor M5A, a first electrode of the fifth transistor M5A is coupled to the second clock signal terminal CLKB, and a second electrode of the fifth transistor M5A is coupled to a first node PD1. A gate electrode of the fifth control transistor M5B is coupled to a first electrode of the fifth control transistor M5B, the first electrode of the fifth control transistor M5B is coupled to the first clock signal terminal CLK, and a second electrode of the fifth control transistor M5B is coupled to the second node PD2. A gate electrode of the sixth transistor M6A is coupled to a third node PU, a first electrode of the sixth transistor M6A is coupled to the first node PD1, and a second electrode of the sixth transistor M6A is coupled to the first level signal terminal LVGL. A gate of the sixth control transistor M6B is coupled to the first electrode of the first capacitor C1, a first electrode of the sixth control transistor M6B is coupled to the second node PD2, and a second electrode of the sixth control transistor M6B is coupled to the first level signal terminal LVGL. A gate electrode of the seventh transistor M7A is coupled to the first output control signal terminal Out_C(n−1), a first electrode of the seventh transistor M7A is coupled to the first node PD1, and a second electrode the seventh transistor M7A is coupled to the first level signal terminal LVGL. A gate electrode of the seventh control transistor M7B is coupled to the first output control signal terminal Out_C(n−1), a first electrode of the seventh control transistor M7B is coupled to the second node PD2, and a second electrode of the seventh control transistor M7B is coupled to the first level signal terminal LVGL. A gate electrode of the eighth transistor M8A is coupled to the first node PD1, a first electrode of the eighth transistor M8A is coupled to the second electrode of the first transistor M1, and a second electrode of the the eighth transistor M8A is coupled to the first level signal terminal LVGL. A gate electrode of the eighth control transistor M8B is coupled to the second node PD2, a first electrode of the eighth control transistor M8B is coupled to the second electrode of the first transistor M1, and a second electrode of the eighth control transistor M8B is coupled to the first level signal terminal LVGL. A gate electrode of the eleventh transistor M11 is coupled to the first electrode of the first capacitor C1, a first electrode of the eleventh transistor M11 is coupled to the first clock signal terminal CLK, and a second electrode of the eleventh transistor M11 is coupled to the second output control signal terminal Out_C(n). A gate electrode of the twelfth transistor M12A is coupled to the first node PD1, a first electrode of the twelfth transistor M12A is coupled to the second output control signal terminal Out_C(n), and a second electrode of the twelfth transistor M12A is coupled to the first level signal terminal LVGL. A gate electrode of the twelfth control transistor M12B is coupled to the second node PD2, a first electrode of the twelfth control transistor M12B is coupled to the second output control signal terminal Out_C(n), and a second electrode of the twelfth control transistor M12B is coupled to the first level signal terminal LVGL. A gate electrode of the thirteenth transistor M13A is coupled to the first node PD1, a first electrode of the thirteenth transistor M13A is coupled to the first cascade output terminal Gout(n), and a second electrode of the thirteenth transistor M13A is coupled to the second level signal terminal VGL. A gate electrode of the thirteenth control transistor M13B is coupled to the second node PD2, a first electrode of the thirteenth control transistor M13B is coupled to the first cascade output terminal Gout(n), and a second electrode of the thirteenth control transistor M13B is coupled to the second level signal terminal VGL. A gate electrode of the fifteenth transistor M15 is coupled to a reset signal terminal T_RST, a first electrode of the fifteenth transistor M15 is coupled to the second electrode of the first transistor M1, and a second electrode of the fifteenth transistor M15 is coupled to the first level signal terminal LVGL.

Exemplarily, in the shift register, transistors with a small channel width-to-length ratio (W/L) are more prone to have a defect of being a conductor. Being conductor refers to the condition where a transistor loses the ability to control its ON or OFF states, essentially becoming a conductor and therefore unable to function properly. For example, the output transistor M4 has a small channel width-to-length ratio (W/L), making it more likely to become a conductor, thereby affecting the proper operation of the shift register. Here, W represents the channel width of the transistor, and L represents the channel length.

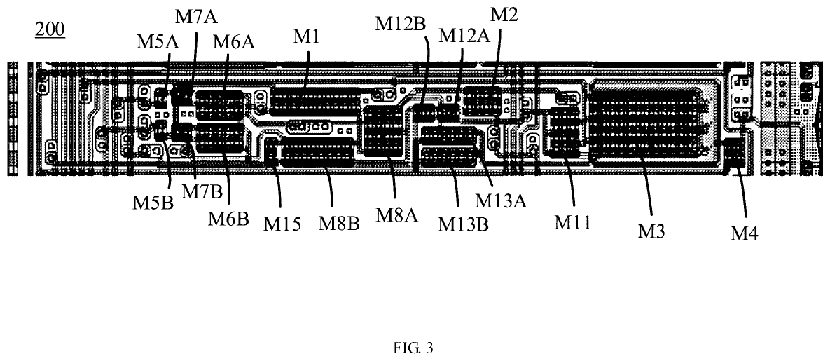

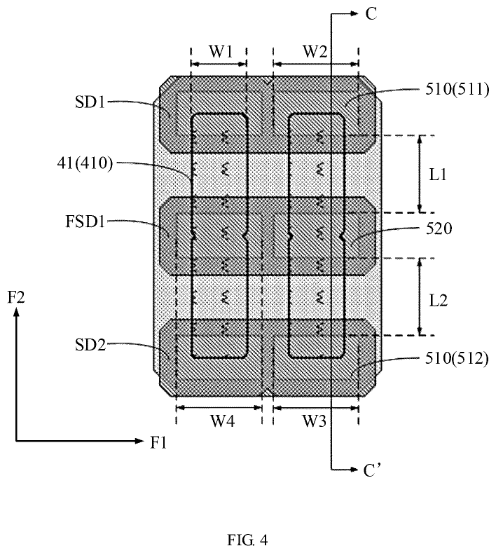

In some embodiments of the disclosure, as shown in FIGS. 3 and 4, the display panel 100 includes a shift register 200, and the shift register 200 includes an output transistor M4.

The semiconductor layer 40 includes an active layer 41 of the output transistor M4.

The source-drain layer 60 includes a first electrode SD1 and a second electrode SD2 of the output transistor M4.

The first contact hole 510 includes a first sub-contact hole 511 and a second sub-contact hole 512; the first electrode SD1 is connected with the active layer 41 through the first sub-contact hole 511, and the second electrode SD2 is connected with the active layer 41 through the second sub-contact hole 512.

Exemplarily, as shown in FIG. 1, the gate conductive layer 20 includes a gate electrode of the output transistor M4.

Exemplarily, as shown in FIGS. 1 and 4, the first electrode SD1 can be the source electrode of the output transistor M4, and the second electrode SD2 can be the drain electrode of the output transistor M4; or, the first electrode SD1 can be the drain electrode of the output transistor M4 and the second electrode SD2 can be the source electrode of the output transistor M4, which is not limited here.

Exemplarily, in the embodiments of the disclosure, the patterned source-drain layer can be directly formed by etching, to form the first electrode and second electrode.

In some embodiments of the disclosure, as shown in FIG. 4, the etch barrier layer 50 also includes a second contact hole 520. An orthographic projection of the second contact hole 520 on the base substrate 10 is located between orthographic projections of the first electrode SD1 and the second electrode SD2 on the base substrate 10. The orthographic projection of the second contact hole 520 on the base substrate and an orthographic projection of the active layer 41 on the base substrate have an overlapping region.

The source-drain layer 60 further includes a first dummy electrode FSD1. An orthographic projection of the first dummy electrode FSD1 on the base substrate 10 is located between the orthographic projections of the first electrode SD1 and the second electrode SD2 on the base substrate 10. The orthographic projection of the first dummy electrode FSD1 on the base substrate covers the orthographic projection of the second contact hole 520 on the base substrate.

Exemplarily, as shown in FIGS. 1 and 4, the orthographic projection of the first electrode SD1 on the base substrate 10 covers an orthographic projection of the first sub-contact hole 511 on the base substrate 10. The orthographic projection of the second electrode SD2 on the base substrate 10 covers an orthographic projection of the second sub-contact hole 512 on the base substrate 10.

Exemplarily, as shown in FIG. 4, a shape of the orthographic projection of the first dummy electrode FSD1 on the base substrate 10 is the same as a shape of the orthographic projections of the first electrode SD1 and a shape of the orthographic projections of the second electrode SD2 on the base substrate 10.

In some embodiments of the disclosure, as shown in FIG. 4, the active layer 41 includes multiple sub-active layers 410. The multiple sub-active layers 410 are arranged at intervals along the first direction F1. The first electrode SD1, the first dummy electrode FSD1, and the second electrode SD2 are arranged at intervals along the second direction F2.

Each of the multiple sub-active layers 410 corresponds to the first sub-contact hole 511, the second sub-contact hole 512, and the second contact hole 520.

In some embodiments of the disclosure, as shown in FIGS. 1 and 4, the first sub-contact hole 511, the second sub-contact hole 512, and the second contact hole 520 are arranged at intervals along the second direction F2.

A minimum distance between an edge of the first sub-contact hole 511 and an edge of the second contact hole 520 along the second direction F2 is indicated as a first length L1.

A minimum distance between an edge of the second sub-contact hole 512 and an edge of the second contact hole 520 along the second direction F2 is indicated as a second length L2.

The ratio between the first length L1 and the second length L2 ranges from 0.8 to 1.

Exemplarily, the ratio between the first length L1 and the second length L2 can be 0.8, 0.85, 0.9, 0.95, 1, etc., which is not limited here.

In some embodiments of the disclosure, as shown in FIG. 4, a width of the sub-active layer 410 in the first direction F1 is indicated as a first width W1, a width of the first sub-contact hole 511 in the first direction F1 is indicated as a second width W2, a width of the second sub-contact hole 512 in the first direction F1 is indicated as a third width W3, and a width of the second contact hole 520 in the first direction F1 is indicated as a fourth width W4. At least one of the second width W2, the third width W3, and the fourth width W4 is larger than the first width W1.

Exemplarily, the second width W2 is larger than the first width W1; the third width W3 is larger than the first width W1; the fourth width W4 is larger than the first width W1, etc., which is not limited here.

In some embodiments of the disclosure, as shown in FIG. 4, two or more of the second width W2, the third width W3, and the fourth width W4 are equal.

Exemplarily, the second width W2, third width W3, and fourth width W4 are all the same; or the second width W2 and third width W3 are equal; or the third width W3 and fourth width W4 are equal; or the second width W2 and fourth width W4 are equal, which are not limited here.

In the embodiments of the disclosure, a first dummy electrode is added between the first electrode and second electrode of the output transistor, and it is ensured that the first electrode, the second electrode, and first dummy electrodes have the same dimensions while controlling the ratio between the first length and the second length. This arrangement ensures that the etching processes for the source-drain layer and the etch barrier layer do not adversely affect the characteristics of the output transistor, reducing the likelihood that the output transistor becomes a conductor, and minimizing the impact on the output transistor's ON-state current.

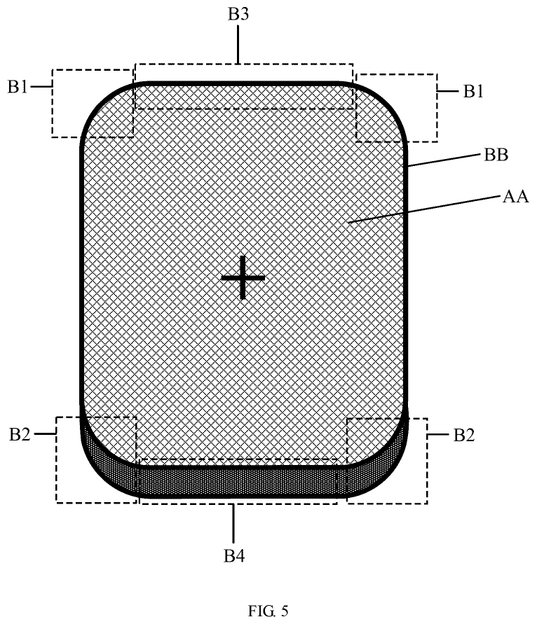

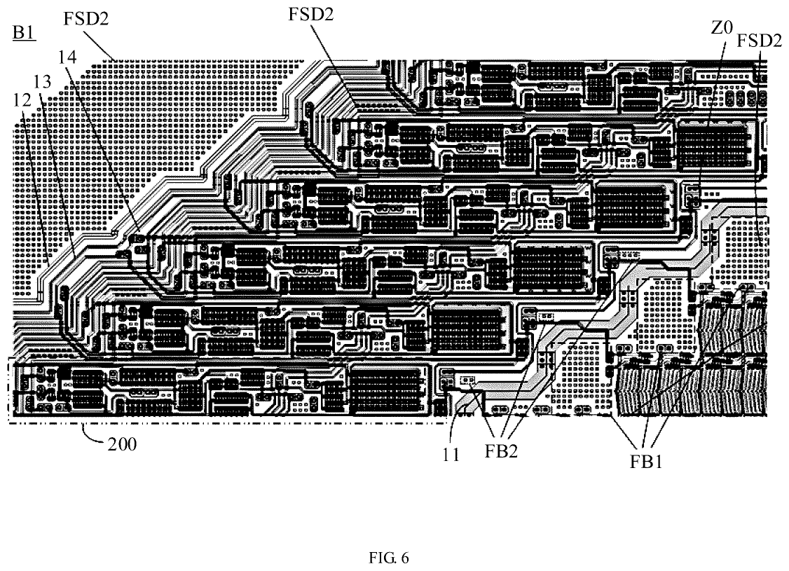

In some embodiments of the disclosure, as shown in FIGS. 5 and 6, the base substrate includes a display region AA and a non-display region BB.

The display region AA is provided with an array arrangement of sub-pixels spx.

The non-display region BB includes a first region B1. The first region B1 is provided with multiple cascaded shift registers 200, multiple transfer holes Z0, and multiple common voltage signal lines 11, and includes a first dummy fill region FB1, and a second dummy fill region FB2.

An orthographic projection of the shift registers 200 and an orthographic projection of the sub-pixels spx are located at different sides of an orthographic projection of the common voltage signal lines 11 on the base substrate 10.

An orthographic projection of the transfer holes Z0 on the base substrate 10 is located between the orthographic projection of the shift registers 200 and the orthographic projection of the common voltage signal lines 11 on the base substrate 10.

An orthographic projection of the first dummy fill regions FB1 on the base substrate 10 is located between the orthographic projection of the sub-pixels spx and the orthographic projection of the common voltage signal lines 11 on the base substrate 10. The first dummy fill region FB1 is provided with multiple second dummy electrodes FSD2 arranged at intervals.

An orthographic projection of the second dummy fill regions FB2 on the base substrate is located between the orthographic projection of the transfer holes Z0 and the common voltage signal lines 11 on the base substrate 10. The second dummy fill region FB2 is provided with multiple second dummy electrodes FSD2 arranged at intervals.

The first region B1 is located at a corner of the base substrate 10.

Exemplarily, the transfer hole Z0 can be used for electrical connection of gate lines, reset signal lines, power voltage signal lines, etc., which can prevent electrostatic accumulation caused by long signal lines crossing other signal lines and subsequently prevent electrostatic breakdown, thus affecting display quality. Exemplarily, the gate lines and reset signal lines are in the gate conductive layer 20, while the power voltage signal lines are in the source-drain layer 60.

Exemplarily, as shown in FIG. 6, the non-display region BB may also be provided with ground signal lines 12, common signal lines 13, and drive signal lines 14. Multiple second dummy electrodes FSD2 are arranged at intervals at one side of the ground signal lines 12. An orthographic projection of part of the drive signal lines 14 on the base substrate 10 overlaps with the orthographic projection of the second dummy electrodes FSD2 on the base substrate 10.

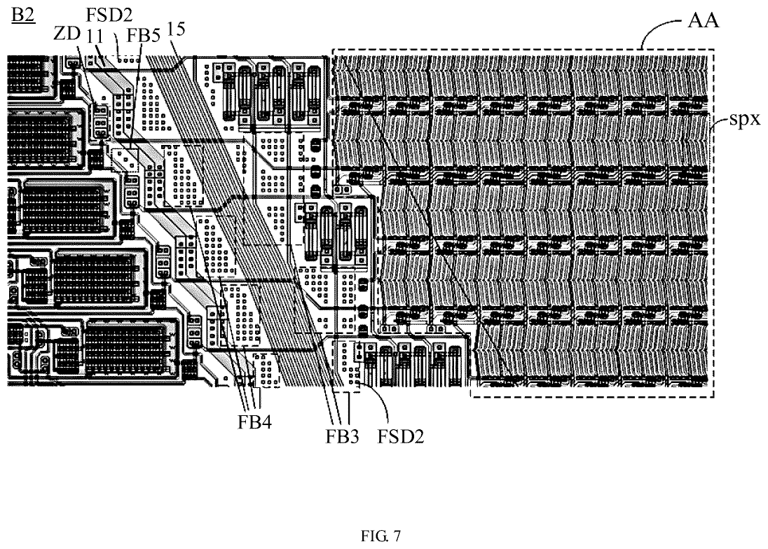

In some embodiments of the disclosure, as shown in FIGS. 5, 7, and 8, the non-display region BB further includes: a second region B2. The second region B2 is provided with multiple cascaded shift registers 200, multiple transfer electrodes ZD, multiple common voltage signal lines 11, and multiple data fan-out lines 15, and includes a third dummy fill region FB3, a fourth dummy fill region FB4, and a fifth dummy fill region FB5.

An orthographic projection of the shift registers 200 and an orthographic projection of the sub-pixels on the base substrate 10 are located at different sides of an orthographic projection of the common voltage signal lines 11 on the base substrate 10.

An orthographic projection of the transfer electrode ZD on the base substrate 10 is located between the orthographic projection of the shift registers 200 and the orthographic projection of the common voltage signal lines 11 on the base substrate 10.

An orthographic projection of the data fan-out lines 15 on the base substrate 10 is located between the orthographic projection of the common voltage signal lines 11 and the orthographic projection of the sub-pixels spx on the base substrate 10.

An orthographic projection of the third dummy fill region FB3 on the base substrate 10 is located between the orthographic projection of the sub-pixels spx and the orthographic projection of the data fan-out lines 15 on the base substrate 10, and the third dummy fill region FB3 is provided with multiple second dummy electrodes FSD2 arranged at intervals.

An orthographic projection of the fourth dummy fill region FB4 on the base substrate 10 is located between the orthographic projection of the common voltage signal lines 11 and the orthographic projection of the data fan-out lines 15 on the base substrate 10, and the fourth dummy fill region FB4 is provided with multiple second dummy electrodes FSD2 arranged at intervals.

An orthographic projection of the fifth dummy fill region FB5 on the base substrate 10 is located between the orthographic projection of the common voltage signal lines 11 and the orthographic projection of the transfer electrodes ZD on the base substrate 10, and the fifth dummy fill region FB5 is provided with multiple second dummy electrodes FSD2 arranged at intervals.

The second region B2 is located at a corner of the base substrate 10.

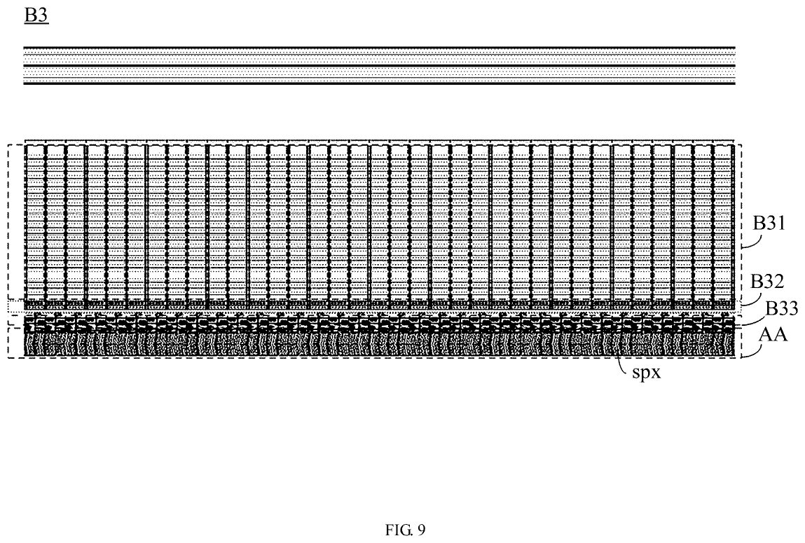

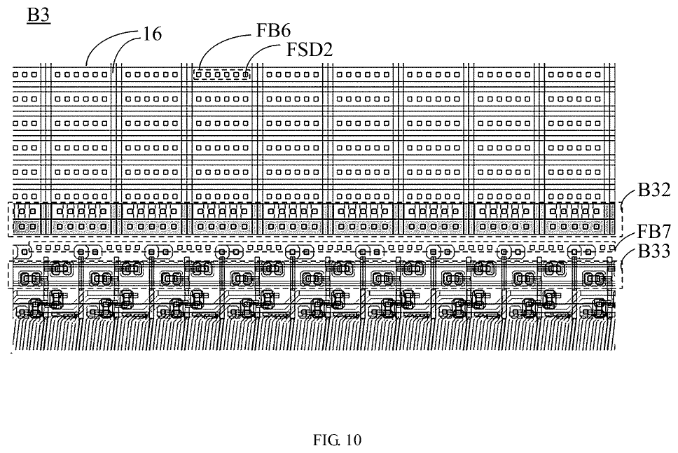

In some embodiments of the disclosure, as shown in FIGS. 5, 9, and 10, the non-display region BB further includes a third region B3. The third region B3 includes a grid-shaped hollow region B31 formed by multiple intersecting common signal lines 16, a transfer region B32, a dummy transistor region B33, a sixth dummy fill region FB6, and a seventh dummy fill region FB7.

An orthographic projection of the transfer region B32 on the base substrate 10 overlaps with an orthographic projection of part of the common signal lines 16 on the base substrate 10.

An orthographic projection of the dummy transistor region B33 on the base substrate 10 is located between the orthographic projection of transfer region B32 and the orthographic projection of the sub-pixels spx on the base substrate 10.

An orthographic projection of the sixth dummy fill region FB6 on the base substrate 10 overlaps with an orthographic projection of the grid-shaped hollow region B31 on the base substrate 10, and the sixth dummy fill region FB6 is provided with multiple second dummy electrodes FSD2 arranged at intervals.

An orthographic projection of the seventh dummy fill region FB7 on the base substrate 10 is located between the orthographic projection of the dummy transistor region B33 and the orthographic projection of the transfer region B32 on the base substrate 10, and the seventh dummy fill region FB7 is provided with multiple second dummy electrodes FSD2 arranged at intervals.

Exemplarily, the common signal lines 16 can be electrically connected with the common electrode layer through the transfer region B32. The common electrode layer is disposed on a side of the second insulating layer facing away from the base substrate.

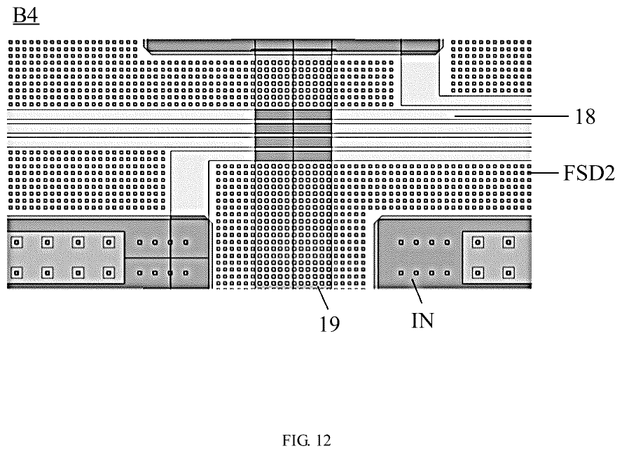

In some embodiments of the disclosure, as shown in FIGS. 5, 11, and 12, the non-display region further includes a fourth region B4. The fourth region B4 is provided with multiple input terminals IN, multiple first conductive signal lines 17, multiple second conductive signal lines 18, multiple test signal lines 19, and multiple second dummy electrodes FSD2, where the multiple second dummy electrodes are arranged at intervals.

The multiple test signal lines 19 correspond one-to-one with multiple input terminals IN; the first conductive signal lines 17 are located at two sides of the input terminals IN, and the second conductive signal lines 18 are located at one side of the input terminals IN.

The orthographic projection of the second dummy electrode FSD on the base substrate 10 does not overlap with an orthographic projection of the first conductive signal lines 17, an orthographic projection of the input terminals IN, or an orthographic projection of the second conductive signal lines 18 on the base substrate 10.

The orthographic projection of the second dummy electrode FSD on the base substrate 10 overlaps or does not overlap with an orthographic projection of the multiple test signal lines 19 on the base substrate.

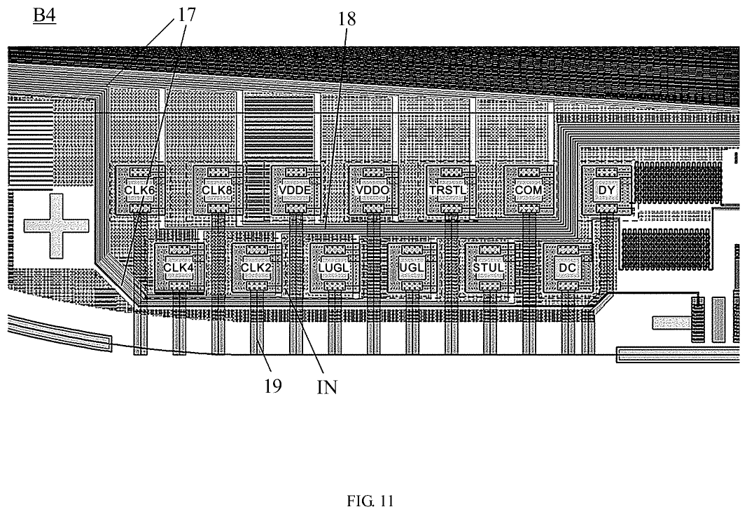

Exemplarily, as shown in FIG. 11, the orthographic projection of the shift registers in the non-display region (not shown in the figure) is located at two sides of the orthographic projection of the input terminals on the base substrate. The input terminal includes multiple output pins. The output pins of the input terminals are electrically connected with the shift registers in the non-display region through the first conductive signal lines to provide the required signals to the shift registers. The second conductive signal lines are electrically connected with the output pins of the input terminals to provide the required signals to the shift registers. The test signal lines are electrically connected with the input terminals for subsequent testing of the display panel. Exemplarily, the input terminal can be a chip (Integrated Circuit Chip, IC).

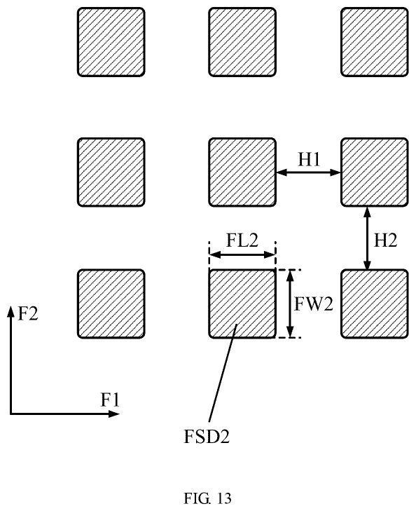

In some embodiments of the disclosure, as shown in FIG. 13, a distance between adjacent second dummy electrodes FSD2 along the first direction F1 is indicated as a first spacing H1, and a distance between adjacent second dummy electrodes FSD2 along the second direction F2 is indicated as the second spacing H2. The length FL2, width FW2 of the second dummy electrode, the first spacing H1, and the second spacing H2 are kept between 2 micrometers and 10 micrometers.

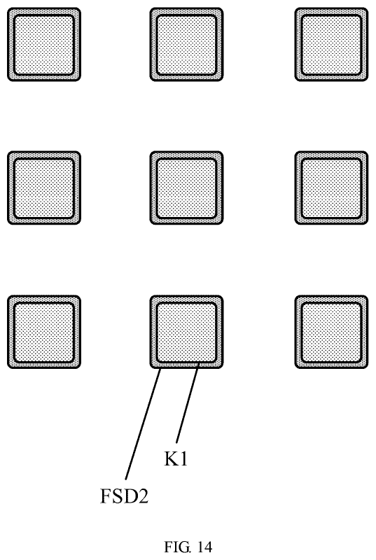

In some embodiments of the disclosure, as shown in FIG. 14, the etch barrier layer 50 has multiple first through holes K1, and at least one second dummy electrode FSD2 corresponds to at least one first through hole K1, with an orthographic projection of the second dummy electrode FSD2 on the base substrate 10 covering an orthographic projection of the corresponding first through hole K1 on the base substrate 10.

It should be noted that a distance between the second dummy electrode FSD2 and surrounding regions such as shift registers and display region is maintained between 3.5 micrometers and 5 micrometers.

Exemplarily, in display panels, the uneven distribution of the source-drain layer and the etch barrier layer can easily cause transistors to become conductors. In the disclosure, unevenness in transistors and graphic-free regions in the display panel can be avoided by setting multiple second dummy electrodes FSD2, thereby reducing the likelihood of transistors becoming conductors and improving display quality. It can also avoid poor display due to insufficient frame sealant support caused by missing parts of the film layer.

Exemplarily, the length FL2, width FW2 of the second dummy electrode, and the first spacing H1 and second spacing H2 can all be the same, partially the same, or entirely different, and this is not limited herein. For example, the length FL2, width FW2 of the second dummy electrode, first spacing H1, and second spacing H2 can all be 4.5 micrometers. Alternatively, the length FL2 and width FW2 of the second dummy electrode can both be 5 micrometers, and both the first spacing H1 and second spacing H2 can be 3 micrometers. There are no limitations in this regard.

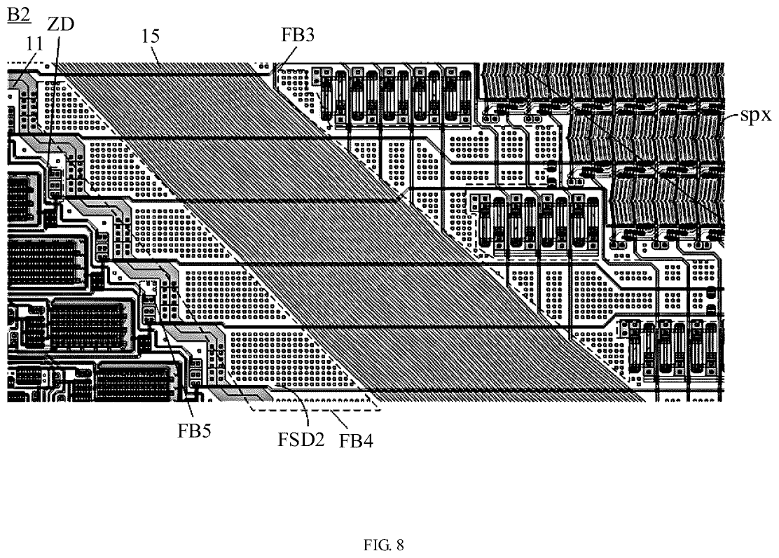

In some embodiments of the disclosure, as shown in FIG. 8, the etch barrier layer 50 has multiple first through holes K1, and at least one second dummy electrode FSD2 corresponds to at least one first through hole K1. The orthographic projection of the second dummy electrode FSD2 on the base substrate 10 covers the orthographic projection of the corresponding first through hole K1 on the base substrate 10.

It should be noted that there are multiple first through holes in the etch barrier layer, and the first through holes are hollowed-out regions, so there is etch barrier layer outside the first through holes.

In the embodiments of the disclosure, by providing the second dummy electrodes FSD2, defect of becoming conductor caused by the absence or extreme uneven density of the source-drain layer in some regions of the display panel can be avoided. However, it cannot significantly optimize or avoid the defect of becoming conductor caused by uneven density of the etch barrier layer. In the disclosure, the issue of becoming conductor caused by uneven density of the etch barrier layer can be avoided by making at least one second dummy electrode FSD2 correspond to at least one first through hole K1.

Exemplarily, the length and width of the first through hole K1 can range from 2 micrometers to 5 micrometers, such as 2 micrometers, 2.5 micrometers, 3 micrometers, 5 micrometers, and so on, which is not limited here. For example, the length and width of the first through hole K1 can be 0-2 micrometers smaller than the length and width of the second dummy electrode FSD2.

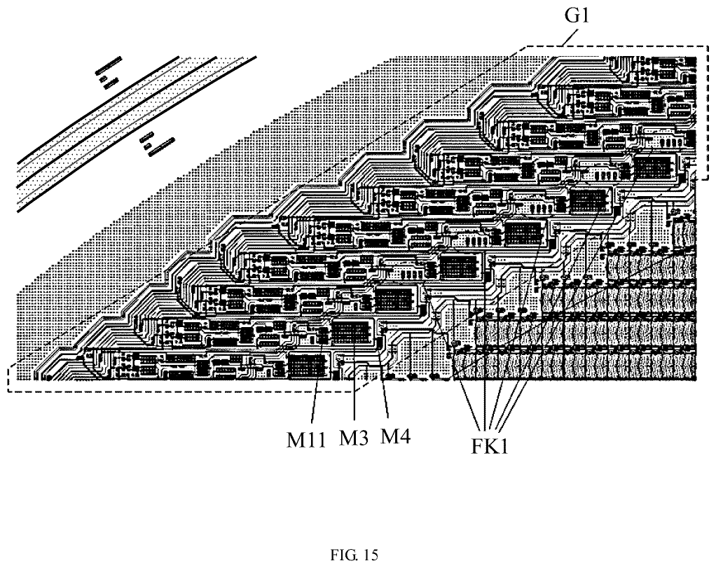

In some embodiments of the disclosure, as shown in FIGS. 15, 17, and 19, the etch barrier layer 50 further includes at least one transfer dummy hole FK1. An orthographic projection of the transfer dummy hole FK1 on the base substrate 10 does not overlap with the orthographic projection of the shift registers 200 on the base substrate 10. The shift registers 200 are located in the first shift register region G1, and the transfer dummy hole FK1 is located in the first shift register region G1. The first shift register region G1 is located at a corner of the base substrate 10.

In some embodiments of the disclosure, as shown in FIGS. 1, 15, 17, and 19, the transfer dummy hole FK1 also passes through the gate insulating layer 30. The first insulating layer 70 is disposed on the side of the source-drain layer 60 facing away from the base substrate 10, and the transfer dummy hole FK1 also passes through the first insulating layer 70. The second insulating layer 80 is disposed on the side of the first insulating layer 70 facing away from the base substrate 10, and the transfer dummy hole FK1 also passes through the second insulating layer 80.

Exemplarily, as shown in FIGS. 15, 17, and 19, the shift register includes an output transistor M4, the third transistor M3, and the eleventh transistor M11. Orthographic projections of the output transistor M4, third transistor M3, and eleventh transistor M11 on the base substrate 10 are located between the orthographic projection of the transfer dummy hole FK1 and the orthographic projection of the common voltage signal lines 11 on the base substrate 10. The output transistor M4, third transistor M3, and eleventh transistor M11 among the transistors in the shift register are closest to the common voltage signal line 11. The orthographic projection of the transfer dummy hole FK1 on the base substrate 10 is located at one side of the orthographic projection of the output transistor M4 on the base substrate 10.

Exemplarily, as shown in FIGS. 15, 17, and 19, there are also multiple second dummy electrodes FSD2 spaced apart from each other in the shift register. The orthographic projections of the second dummy electrodes FSD2 on the base substrate 10 do not overlap with the orthographic projections of the transistors in the shift register on the base substrate 10. The orthographic projections of the second dummy electrodes FSD2 on the base substrate 10 also do not overlap with the orthographic projections of the transfer dummy hole FK1 on the base substrate 10.

Exemplarily, as shown in FIGS. 15, 17, and 19, in the corner area of the display panel, due to wiring reasons, at least one output transistor M4, third transistor M3, and eleventh transistor M11 of the shift register need to keep a certain distance from other transistors in the shift register (e.g., 30 μm to 500 μm). Therefore, blank regions may remain, leading to uneven film layers. In the disclosure, uneven film layers can be improved by setting transfer dummy holes in the blank regions left in the shift register, thus avoiding the issue of becoming conductors.

Exemplarily, as shown in FIGS. 15, 17, and 19, the transfer dummy holes correspond to layers including not only the gate conductive layer and source-drain layer, but also the etch barrier layer, first insulating layer, and second insulating layer. This effectively improves the film layers around the shift register, making the surrounding film layers more uniform, thereby avoiding the issue of the transistors in the shift register becoming conductors.

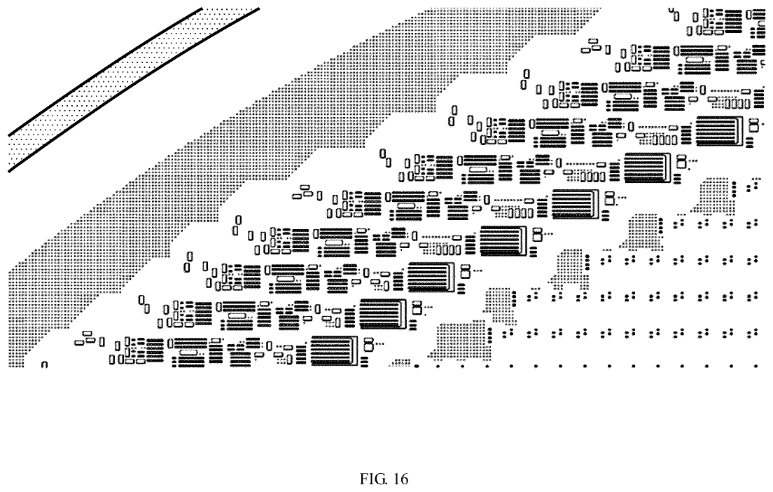

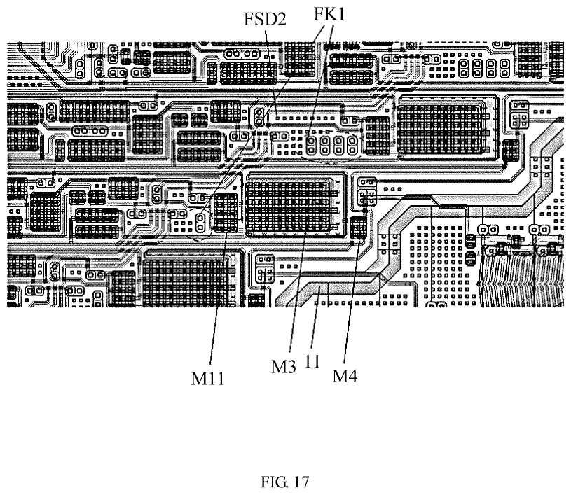

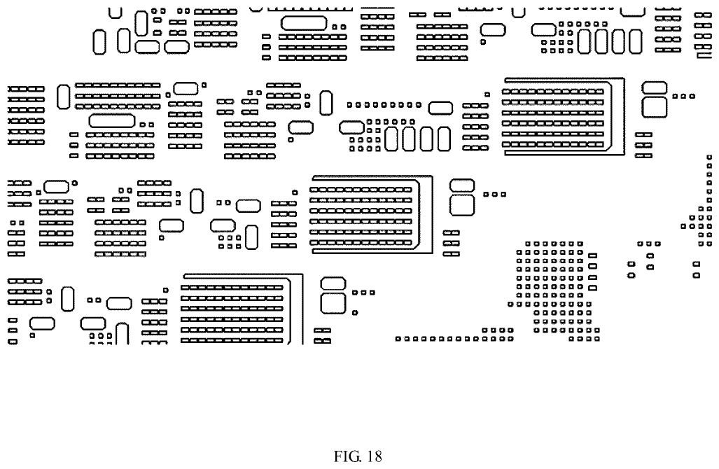

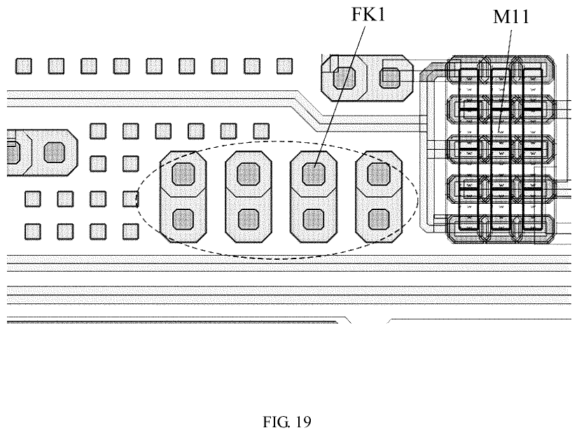

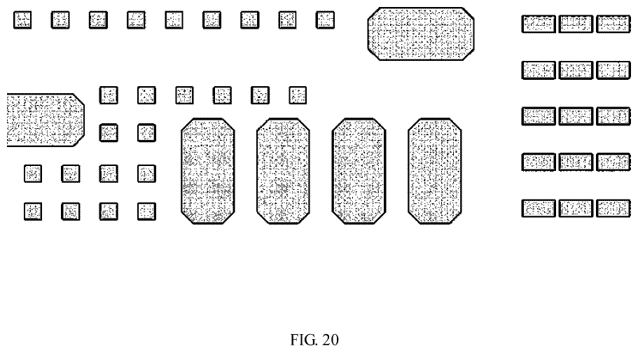

Exemplarily, FIG. 16 shows the through holes of the etch barrier layer in FIG. 15; FIG. 18 shows the through holes of the etch barrier layer in FIG. 17; FIG. 20 shows the through holes of the etch barrier layer in FIG. 19.

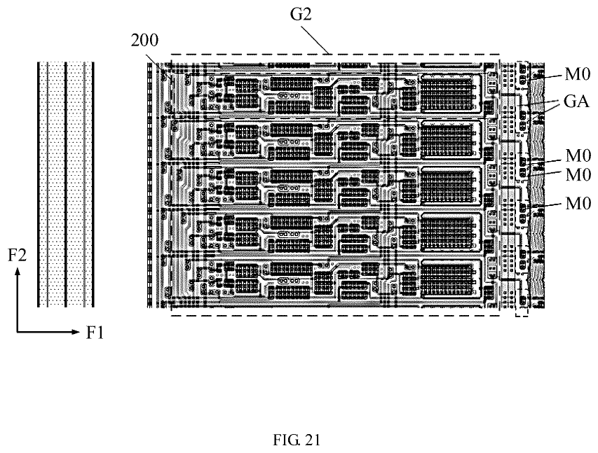

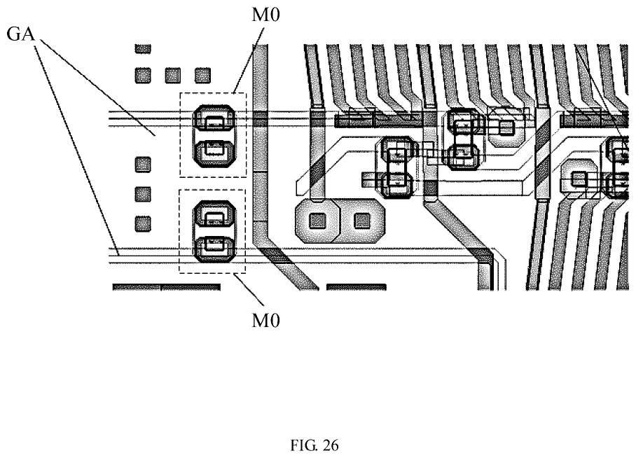

In some embodiments of the disclosure, as shown in FIGS. 21 to 26, the gate conductive layer 20 includes multiple gate lines GA, and the display panel further includes at least one dummy transistor M0. One end of at least one gate line GA among the multiple gate lines GA is connected with at least one dummy transistor M0.

In some embodiments of the disclosure, as shown in FIGS. 21 to 26, the same end of each of the multiple gate lines GA is connected with at least one dummy transistor M0.

In some embodiments of the disclosure, as shown in FIGS. 21 to 24, the display panel includes a display region AA and a non-display region BB. The display region AA is provided with an array of sub-pixels spx. The non-display region BB is provided with multiple shift registers 200, and the display region AA is provided with multiple gate lines GA. The multiple shift registers 200 are correspondingly connected with the multiple gate lines GA. An orthographic projection of at least one dummy transistor M0 on the base substrate 10 is located between the orthographic projection of the shift register 200 on the base substrate 10 and the orthographic projection of the corresponding connected gate line GA on the base substrate 10.

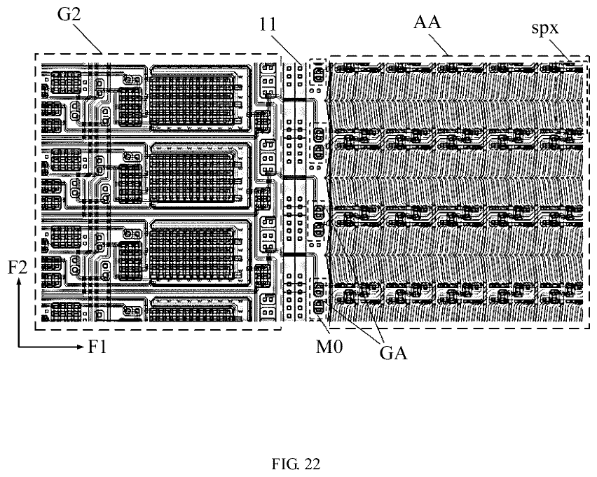

In some embodiments of the disclosure, as shown in FIGS. 21 and 22, multiple shift registers are located in the second shift register region G2. The shift registers in the second shift register region G2 are arranged in sequence along the second direction F2. The orthographic projection of the dummy transistors M0 on the base substrate 10 is located between the orthographic projection of the sub-pixels spx on the base substrate 10 and the orthographic projection of the second shift register region G2 on the base substrate 10. The dummy transistor M0 is arranged at the side away from the sub-pixels spx along the first direction F1. Orthographic projections of adjacent dummy transistors M0 on the base substrate 10 are arranged opposite each other along the second direction F2.

Exemplarily, as shown in FIGS. 21 and 22, the second shift register region is located at a vertical edge of the base substrate.

Exemplarily, the dummy transistor does not have corresponding pixel electrode or the like.

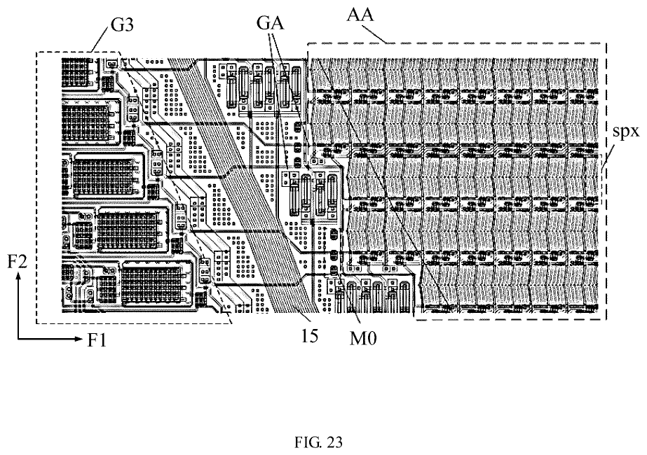

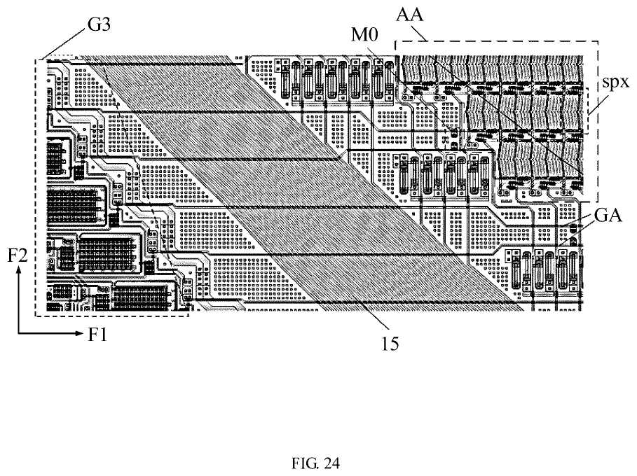

In some embodiments of the disclosure, as shown in FIGS. 23 and 24, multiple shift registers are located in the third shift register region G3. Multiple data fan-out lines 15 are arranged between the third shift register region G3 and the sub-pixels spx. The orthographic projection of the dummy transistor M0, which is connected with one end of the gate line GA near the shift register 200, is located between the orthographic projection of the data fan-out lines 15 and the projection of the sub-pixels spx on the base substrate 10. The dummy transistor M0 is arranged at the side that is away from the sub-pixels spx along the first direction F1. Orthographic projections of adjacent dummy transistors M0 on the base substrate 10 are positioned opposite each other along the second direction F2.

Exemplarily, as shown in FIGS. 23 and 24, the third shift register region is located at the corner of the base substrate.

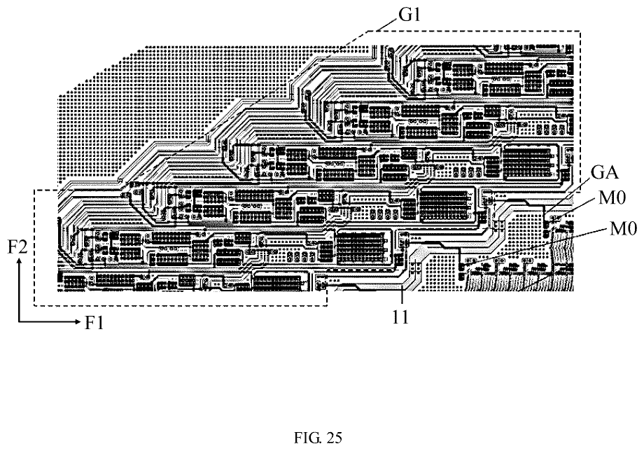

Exemplarily, as shown in FIG. 25, multiple shift registers are located in the first shift register region G1. Multiple common voltage signal lines 11 are arranged between the first shift register region G1 and the sub-pixels spx. The orthographic projection of the dummy transistor M0, which is connected with one end of the gate line GA near the shift register 200, is positioned between the orthographic projection of the data fan-out lines 15 and the orthographic projection of the sub-pixels spx on the base substrate 10. The dummy transistor M0 is arranged at the side that is away from the sub-pixels spx along the first direction F1. Orthographic projections of adjacent dummy transistors M0 on the base substrate 10 are positioned opposite each other along the second direction F2.

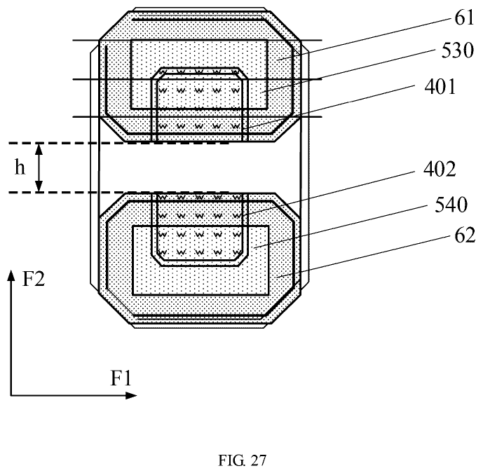

In some embodiments of the disclosure, as shown in FIG. 27, the semiconductor layer 40 further includes: a first active layer 401 and a second active layer 402 of the dummy transistor M0.

The source-drain layer 60 further includes: a first electrode 61 and a second electrode 62 of the dummy transistor M0.

The etch barrier layer 50 further includes a third contact hole 530 and a fourth contact hole 540.

The first electrode 61 of the dummy transistor M0 is connected with the first active layer 401 through the third contact hole 530, and the second electrode 62 of the dummy transistor M0 is connected with the second active layer 402 through the fourth contact hole 540.

In some embodiments of the disclosure, as shown in FIG. 27, the first active layer 401 and the second active layer 402 are arranged at intervals along the second direction F2, and the first electrode 61 and second electrode 62 of the dummy transistor M0 are also arranged at intervals along the second direction F2.

Exemplarily, because transistors at the edge of the display region are prone to becoming conductors or generating defects due to electrostatic discharge (ESD), in the related art, commonly dummy sub-pixels are used to prevent transistors at the edge of the display region from becoming conductors or generating defects due to ESD. However, to achieve a narrow bezel, there is no space left to arrange dummy sub-pixels. In the disclosure, by arranging dummy transistors with the same size or a similar size as the transistors in the sub-pixels at both ends of the gate lines (the specific positions can be set according to the available space and do not have to be immediately adjacent to the sub-pixels in the display region), the narrow bezel requirement can be met, and the issue of becoming conductors and defects caused by ESD can also be avoided.

Exemplarily, as shown in FIG. 27, a distance between the first active layer and the second active layer is h (generally, h is not less than 2 μm). If electrostatic discharge occurs, it can first break down the dummy transistor, thereby preventing breakdown of the transistors in the display region.

Based on the same concept, embodiments of the disclosure also provide a display apparatus including the display panel according to the above embodiments of the disclosure. The principle of problem-solving for the display apparatus is similar to that of the aforementioned display panel, therefore, the implementation of the display apparatus can refer to the implementation of the aforementioned display panel, and the repetition will not be elaborated here.

In specific implementations, in the embodiments of the disclosure, the display apparatus may be any product or component with a display function, such as a mobile phone, tablet, television, monitor, laptop, digital photo frame, navigator, etc. Other essential components of the display apparatus, which should be understood by those skilled in the art, are not described here and should not be considered as limitations of the disclosure.

Although the preferred embodiments of the disclosure have been described, those skilled in the art can make additional changes and modifications to these embodiments once they know the basic inventive concepts. Therefore, the appended claims are intended to be explained as including the preferred embodiments and all changes and modifications falling within the scope of the disclosure.

Obviously, those skilled in the art can make various changes and modifications to the embodiments of the disclosure without departing from the spirit and scope of the embodiments of the disclosure. Thus, if these changes and modifications of the embodiments of the disclosure fall within the scope of the claims of the disclosure and their equivalents, the disclosure is also intended to include these changes and modifications.

1.-22. (canceled)

23. A display panel, comprising:
a base substrate;
a gate conductive layer on the base substrate;
a gate insulating layer on a side of the gate conductive layer facing away from the base substrate;
a semiconductor layer on a side of the gate insulating layer facing away from the base substrate;
an etch barrier layer on a side of the semiconductor layer facing away from the base substrate, wherein the etch barrier layer comprises a first contact hole; and
a source-drain layer on a side of the etch barrier layer facing away from the base substrate, wherein the source-drain layer is connected with the semiconductor layer through the first contact hole.

24. The display panel according to claim 23, wherein the display panel comprises a shift register, and the shift register comprises an output transistor;
the semiconductor layer comprises an active layer of the output transistor;
the source-drain layer comprises a first electrode and a second electrode of the output transistor;
the first contact hole comprises a first sub-contact hole and a second sub-contact hole, the first electrode of the output transistor is connected with the active layer through the first sub-contact hole, and the second electrode of the output transistor is connected with the active layer through the second sub-contact hole;
the etch barrier layer further comprises a second contact hole, an orthographic projection of the second contact hole on the base substrate is located between orthographic projections of the first electrode and the second electrode of the output transistor on the base substrate, and the orthographic projection of the second contact hole on the base substrate and an orthographic projection of the active layer on the base substrate have an overlapping region;
the source-drain layer further comprises a first dummy electrode, an orthographic projection of the first dummy electrode on the base substrate is located between the orthographic projections of the first electrode and the second electrode of the output transistor on the base substrate, and covers the orthographic projection of the second contact hole on the base substrate.

25. The display panel according to claim 24, wherein the active layer comprises a plurality of sub-active layers arranged at intervals along a first direction;
the first electrode of the output transistor, the first dummy electrode, and the second electrode of the output transistor are arranged at intervals along a second direction;
each sub-active layer of the plurality of sub-active layers corresponds to the first sub-contact hole, the second sub-contact hole, and the second contact hole.

26. The display panel according to claim 25, wherein the first sub-contact hole, the second contact hole, and the second sub-contact hole are arranged at intervals along the second direction;
a minimum distance between an edge of the first sub-contact hole and an edge of the second contact hole along the second direction is indicated as a first length;
a minimum distance between an edge of the second sub-contact hole and an edge of the second contact hole along the second direction is indicated as a second length; and
a ratio between the first length and the second length ranges from 0.8 to 1.

27. The display panel according to claim 26, wherein
a width of the active layer in the first direction is indicated as a first width;
a width of the first sub-contact hole in the first direction is indicated as a second width;
a width of the second sub-contact hole in the first direction is indicated as a third width; and
a width of the second contact hole in the first direction is indicated as a fourth width;
wherein at least one of the second width, the third width, or the fourth width is greater than the first width.

28. The display panel according to claim 27, wherein two or more of the second width, the third width, and the fourth width are equal.

29. The display panel according to claim 23, wherein the base substrate comprises a display region and a non-display region;
the display region is provided with an array of sub-pixels, and the non-display region comprises a first region;
the first region is provided with a plurality of cascaded shift registers, a plurality of transfer holes and a plurality of common voltage signal lines, and comprises a first dummy fill region, and a second dummy fill region;
wherein an orthographic projection of the shift registers and an orthographic projection of the sub-pixels on the base substrate are at different sides of an orthographic projection of the common voltage signal lines on the base substrate;
an orthographic projection of the transfer holes on the base substrate is located between the orthographic projection of the shift registers and the orthographic projection of the common voltage signal lines on the base substrate;
an orthographic projection of the first dummy fill region on the base substrate is located between the orthographic projection of the sub-pixels and the orthographic projection of the common voltage signal lines on the base substrate, and the first dummy fill region is provided with a plurality of second dummy electrodes arranged at intervals;
an orthographic projection of the second dummy fill region on the base substrate is located between the orthographic projection of the transfer holes and the orthographic projection of the common voltage signal lines on the base substrate, and the second dummy fill region is provided with a plurality of second dummy electrodes arranged at intervals; and
the first region is located at a corner of the base substrate.

30. The display panel according to claim 29, wherein the non-display region further comprises a second region, and the second region is provided with a plurality of cascaded shift registers, a plurality of transfer electrodes, a plurality of common voltage signal lines and a plurality of data fan-out lines, and comprises a third dummy fill region, a fourth dummy fill region, and a fifth dummy fill region;
wherein in the second region:
an orthographic projection of the shift registers and an orthographic projection of the sub-pixels on the base substrate are at different sides of an orthographic projection of the common voltage signal lines on the base substrate;
an orthographic projection of the transfer electrodes on the base substrate is located between the orthographic projection of the shift registers and the orthographic projection of the common voltage signal lines on the base substrate;
an orthographic projection of the data fan-out lines on the base substrate is located between the orthographic projection of the common voltage signal lines and the orthographic projection of the sub-pixels on the base substrate;
an orthographic projection of the third dummy fill region on the base substrate is located between the orthographic projection of the sub-pixels and the orthographic projection of the data fan-out lines on the base substrate, and the third dummy fill region is provided with a plurality of second dummy electrodes arranged at intervals;
an orthographic projection of the fourth dummy fill region on the base substrate is located between the orthographic projection of the common voltage signal lines and the orthographic projection of the data fan-out lines on the base substrate, and the fourth dummy fill region is provided with a plurality of second dummy electrodes arranged at intervals;
an orthographic projection of the fifth dummy fill region on the base substrate is located between the orthographic projection of the common voltage signal lines and the orthographic projection of the transfer electrodes on the base substrate, and the fifth dummy fill region is provided with a plurality of second dummy electrodes arranged at intervals;
wherein the second region is located at a corner of the base substrate.

31. The display panel according to claim 29, wherein the non-display region further comprises a third region, and the third region comprises a grid-shaped hollow region formed by a plurality of intersecting common signal lines, a transfer region, a dummy transistor region, a sixth dummy fill region, and a seventh dummy fill region;
wherein an orthographic projection of the transfer region on the base substrate overlaps with an orthographic projection of part of the common signal lines on the base substrate;
an orthographic projection of the dummy transistor region on the base substrate is located between the orthographic projection of the transfer region and the orthographic projection of the sub-pixels on the base substrate;
an orthographic projection of the sixth dummy fill region on the base substrate overlaps with an orthographic projection of the grid-shaped hollow region on the base substrate, and the sixth dummy fill region is provided with a plurality of second dummy electrodes arranged at intervals;
an orthographic projection of the seventh dummy fill region on the base substrate is located between the orthographic projection of the dummy transistor region and the orthographic projection of the transfer region on the base substrate, and the seventh dummy fill region is provided with a plurality of second dummy electrodes arranged at intervals.

32. The display panel according to claim 29, wherein the non-display region further comprises a fourth region, and the fourth region is provided with a plurality of input terminals, a plurality of first conductive signal lines, a plurality of second conductive signal lines, a plurality of test signal lines, and a plurality of second dummy electrodes, wherein the plurality of second dummy electrodes in the fourth region are arranged at intervals;
wherein the plurality of test signal lines correspond one-to-one with the plurality of input terminals, the first conductive signal lines are located at two sides of the input terminals, and the second conductive signal lines are located at one side of the input terminals;
the orthographic projection of the second dummy electrodes in the fourth region on the base substrate does not overlap with orthographic projections of the first conductive signal lines, the input terminals, and the second conductive signal lines on the base substrate; and
the orthographic projection of the second dummy electrodes in the fourth region on the base substrate overlap with or does not overlap with orthographic projections of the plurality of test signal lines on the base substrate.

33. The display panel according to claim 29, wherein
a spacing between adjacent second dummy electrodes along a first direction is indicated as a first spacing; and
a spacing between adjacent second dummy electrodes along a second direction is indicated as a second spacing;
wherein a length of the second dummy electrode, a width of the second dummy electrode, the first spacing and the second spacing are kept between 2 micrometers and 10 micrometers.

34. The display panel according to claim 33, wherein the etch barrier layer has a plurality of first through holes, and at least one second dummy electrode corresponds to at least one first through hole;
an orthographic projection of the second dummy electrode on the base substrate covers an orthographic projection of a corresponding first through hole on the base substrate.

35. The display panel according to claim 23, wherein the etch barrier layer further comprises at least one transfer dummy hole;
an orthographic projection of the transfer dummy hole on the base substrate does not overlap with an orthographic projection of a shift register on the base substrate;
wherein the shift register is located in a first shift register region;
the transfer dummy hole is located in the first shift register region; and
the first shift register region is located at a corner of the base substrate.

36. The display panel according to claim 35, wherein
the transfer dummy hole passes through the gate insulating layer;
the transfer dummy hole passes through a first insulating layer on a side of the source-drain layer facing away from the base substrate; and
the transfer dummy hole further passes through a second insulating layer on a side of the first insulating layer facing away from the base substrate.

37. The display panel according to claim 23, wherein the gate conductive layer comprises a plurality of gate lines, and the display panel further comprises at least one dummy transistor;
wherein one end of at least one gate line among the plurality of gate lines is connected with at least one dummy transistor.

38. The display panel according to claim 37, wherein a same end of each gate line among the plurality of gate lines is connected with at least one dummy transistor.

39. The display panel according to claim 37, wherein the display panel comprises a display region and a non-display region, the display region is provided with an array of sub-pixels, the non-display region is provided with a plurality of shift registers, and the display region is provided with a plurality of gate lines;
wherein the plurality of shift registers and the plurality of gate lines are correspondingly connected; and
an orthographic projection of at least one dummy transistor on the base substrate is located between orthographic projections of a shift register and a correspondingly connected gate line on the base substrate.

40. The display panel according to claim 39, wherein the plurality of shift registers are located in a second shift register region, and the shift registers in the second shift register region are arranged sequentially along the second direction;
an orthographic projection of the dummy transistor on the base substrate is located between an orthographic projection of the sub-pixels and an orthographic projection of the second shift register region on the base substrate;
the dummy transistors are located at a side away from the sub-pixels along a first direction, and orthographic projections of adjacent dummy transistors on the base substrate are opposite each other along a second direction;
or
wherein the plurality of shift registers are located in a third shift register region, and a plurality of data fan-out lines are provided between the third shift register region and the sub-pixels;
an orthographic projection of a dummy transistor connected with an end of a gate line near the shift registers is located between an orthographic projection of the data fan-out lines and an orthographic projection of the sub-pixels on the base substrate;
wherein the dummy transistor is located at a side away from the sub-pixels along a first direction, and orthographic projections of adjacent dummy transistors on the base substrate are opposite each other along the second direction.

41. The display panel according to claim 39, wherein the semiconductor layer further comprises a first active layer and a second active layer of the dummy transistor;
the source-drain layer further comprises a first electrode and a second electrode of the dummy transistor; and
the etch barrier layer further comprises a third contact hole and a fourth contact hole;
wherein the first electrode of the dummy transistor is connected with the first active layer through the third contact hole, and the second electrode of the dummy transistor is connected with the second active layer through the fourth contact hole; and
the first active layer and the second active layer are arranged at intervals along a second direction, and the first electrode and the second electrode of the dummy transistor are arranged at intervals along the second direction.

42. A display apparatus comprising the display panel according to claim 23.
